(19) United States
(12) Patent Application Publication
(10) Pub. No.: US 2026/0142124 A1
(43) Pub. Date: May 21, 2026

(54) PLASMA UNIFORMITY CONTROL SYSTEM AND METHODS FOR PROCESSING A SEMICONDUCTOR SUBSTRATE

(71) Applicant: Applied Materials, Inc., Santa Clara, CA (US)

(72) Inventors: Yogananda SARODE VISHWANATH, Bangalore (IN); Kartik RAMASWAMY, San Jose, CA (US)

(21) Appl. No.: 18/952,730

(22) Filed: Nov. 19, 2024

(51) Int. Cl. H01J 37/32

(52) U.S. Cl. CPC H01J 37/3211; H01J 37/32174; H01J 37/32651

(57) ABSTRACT

Methods and apparatus for processing a substrate using a plasma processing assembly. One example plasma processing assembly includes a processing chamber including a processing region, a plasma screen disposed within the processing region that forms a first region of the processing region and a second region of the processing region, a substrate support assembly disposed within the processing region, and a field generation system. The field generation system generally includes a first coil assembly including one or more first coils, where the one or more first coils are aligned in a first direction and at least partially encircle the processing region and where the first coil assembly is disposed inside the first region, and a second coil assembly including one or more second coils, where the one or more second coils at least partially encircle the processing region and the second coil assembly is disposed inside the second region.

### BACKGROUND

### Field

Embodiments of the present disclosure generally relate to a system used in semiconductor device manufacturing. More specifically, embodiments of the present disclosure relate to a plasma processing assembly used to plasma process a substrate and methods of using the same.

### Description of the Related Art

Reliably producing high aspect ratio features is one of the key technology challenges for the next generation of semiconductor devices. One method of forming high aspect ratio features uses a plasma-assisted etching process to bombard a material formed on a surface of a substrate through openings formed in a patterned mask layer formed on the substrate surface.

With technology nodes advancing towards two nanometers (nm), the fabrication of smaller features with larger aspect ratios requires atomic precision for plasma processing. For etching processes where the plasma ions play a major role, ion energy control is always challenging the development of reliable and repeatable device formation processes in the semiconductor equipment industry. In a typical plasma-assisted etching process, the substrate is positioned on a substrate support disposed in a plasma processing chamber, a plasma is formed over the substrate by use of a radio frequency (RF) generator that is coupled to an electrode disposed on or within the plasma processing chamber, and ions are accelerated from the plasma towards the substrate across a plasma sheath. Additionally, RF substrate biasing methods, which require the use of a separate RF biasing source in addition to the RF generator that is used to initiate and maintain the plasma in the plasma processing chamber, have been unable to desirably control the plasma sheath properties to achieve desirable plasma processing results that will allow the formation of these smaller device feature sizes.

However, non-uniformities in the plasma density and/or in the shape of the plasma sheath can occur, due to the variations in the electrical characteristics of and/or spatial arrangement of the processing components disposed within a processing region of the plasma processing chamber. One common plasma density variation is created within conventional inductively coupled plasma sources that include a coil that is positioned over the processing region of the plasma processing chamber due to structural, alignment, and/or orientation variations found of conventional coil designs that often create plasma non-uniformity and both local and global tilt variations in the plasma processing results achieved on substrates processed in the plasma processing chamber. The variation in plasma uniformity and tilt of the sheath created by a coil will cause undesirable processing results, such as deposition or etching non-uniformity, in the deposited layers or etched features formed across the surface of the substrate. Excessive variation in plasma non-uniformity will adversely affect the process results and reduce device yield. Such non-uniformities are often particularly pronounced near or between the center and edge of the substrate.

Accordingly, there is a need in the art for eliminating (or at least minimizing) the adverse effects of plasma non-uniformity inside the plasma processing chamber to solve the problems described above.

### SUMMARY

To the accomplishment of the foregoing and related ends, the one or more aspects comprise the features hereinafter fully described and particularly pointed out in the claims. The following description and the appended drawings set forth in detail certain illustrative features of the one or more aspects. These features are indicative, however, of but a few of the various ways in which the principles of various aspects may be employed.

Embodiments provided herein generally include apparatus, plasma processing assemblies, and methods for plasma processing of a substrate in a plasma processing chamber.

Embodiments of the present disclosure provide a plasma processing assembly. The plasma processing assembly generally includes a processing chamber including a processing region, a plasma screen disposed within the processing region that forms a first region of the processing region and a second region of the processing region, a substrate support assembly disposed within the processing region, the substrate support assembly including a substrate supporting surface, and a field generation system. The field generation system generally includes a first coil assembly including one or more first coils that at least partially encircle the processing region, where windings of the one or more first coils are aligned in a first direction and where the first coil assembly is disposed inside the first region, and a second coil assembly including one or more second coils that at least partially encircle the processing region, where the second coil assembly is disposed inside the second region.

Embodiments of the present disclosure are directed to a method of processing a substrate. The method generally includes performing a processing sequence on the substrate disposed within a processing region of a plasma processing assembly, where the processing sequence includes: (i) biasing, using one or more first power supply circuits, at least one of one or more first coils included in a first coil assembly, where windings of the one or more first coils are aligned in a first direction and at least partially encircle the processing region, the first coil assembly is disposed inside a first region of the processing region formed by a plasma screen disposed within the processing region, and the first direction is at an angle to a plane of the substrate supporting surface in the plasma processing assembly, and (ii) biasing, using one or more second power supply circuits, at least one of one or more second coils included in a second coil assembly, where the one or more second coils at least partially encircle the processing region, and the second coil assembly is disposed inside a second region of the processing region formed by the plasma screen.

Embodiments of the present disclosure provide plasma processing assembly. The plasma processing assembly generally includes a processing chamber including a processing region, a plasma screen disposed within the processing region that forms a first region of the processing region and a second region of the processing region, a substrate support assembly disposed within the processing region, the substrate support assembly including a substrate supporting surface, and a field generation system. The field generation system includes a coil assembly including one or more concentrically wound coils, where windings of the one or more concentrically wound coils are aligned in a direction and at least partially encircle the processing region, the coil assembly is disposed inside the first region, and the direction is at an angle to a plane of the substrate supporting surface.

### BRIEF DESCRIPTION OF THE DRAWINGS

So that the manner in which the above-recited features of the present disclosure can be understood in detail, a more particular description of the disclosure, briefly summarized above, may be had by reference to embodiments, some of which are illustrated in the appended drawings. It is to be noted, however, that the appended drawings illustrate only exemplary embodiments and are therefore not to be considered limiting of its scope and may admit to other equally effective embodiments.

FIG. 1 is a schematic, cross-sectional view of a plasma processing assembly that may be configured to practice the methods set forth herein.

FIGS. 2A-2C are simplified schematic side cross-sectional views of plasma processing assemblies that include field generation systems, according to one or more embodiments of the present disclosure.

FIGS. 3A-3C are simplified schematic side cross-sectional views of plasma processing assemblies that include field generation systems with slanted coils, according to one or more embodiments of the present disclosure.

FIG. 3D is a schematic top view of a plasma screen included in the plasma processing assemblies of FIGS. 2A-2C and 3A-3C, according to one or more embodiments of the present disclosure.

FIGS. 4A-4D are simplified schematic side cross-sectional views of plasma processing assemblies that include field generation systems with coils embedded in plasma screen, according to one or more embodiments of the present disclosure.

FIG. 4E is a schematic top view of a plasma screen included in a plasma processing assemblies of FIGS. 4A-4D, according to one or more embodiments of the present disclosure.

FIG. 5 is a flow diagram depicting example operations for processing a semiconductor substrate, according to one or more of the embodiments described herein.

To facilitate understanding, identical reference numerals have been used, where possible, to designate identical elements that are common to the figures. It is contemplated that elements and features of one implementation may be beneficially incorporated in other implementations without further recitation.

### DETAILED DESCRIPTION

Embodiments of the present disclosure generally relate to a plasma processing assembly used to plasma process a semiconductor substrate. More specifically, embodiments provided in the present disclosure generally include apparatus and methods for delivering and controlling (e.g., tuning) magnetic fields generated from a field generation system disposed within a plasma processing assembly that includes a plasma processing chamber to control a plasma formed therein during semiconductor substrate processing. The apparatus and methods disclosed herein can be useful to mitigate the effects of plasma non-uniformity on a semiconductor substrate during plasma processing.

The plasma processing apparatus and methods described herein are configured to improve the control of various characteristics of the generated plasma and control an ion energy distribution (IED) of the plasma generated ions that interact with a surface of a substrate during plasma processing. The ability to control the magnetic fields generated from the field generation system during processing allows for improved control of one or more characteristics of the generated plasma, such as plasma uniformity, plasma density and shape, local and global tilt in deposited layers or etched features formed in a substrate, IED, electron energy distribution (EED), and other useful parameters. The improved control of the plasma is used to enhance the plasma processing performed in the plasma processing assembly, for example, by forming desirable high-aspect ratio features in the surface of the semiconductor substrate using a reactive ion etching (RIE) process. As a result, greater precision for plasma processing of the semiconductor substrate can be achieved. Furthermore, the apparatus and methods disclosed herein may expand process pulsing windows, limit the interaction of the plasma with interior walls of the plasma processing assembly by confining the plasma volume magnetically (while maintaining plasma uniformity) to prevent damage and prolong the life of the plasma processing assembly, and unlock increased power savings (i.e., decreased power consumption).

In some embodiments, the field generation system may include at least one of a first coil assembly and a second coil assembly both disposed inside a processing region of a plasma processing assembly. The first coil assembly may include one or more first electromagnetic coils coupled to a chamber liner of the plasma processing assembly and may be configured to generate a tunable magnetic field that is configured to adjust characteristics of a plasma generated inside the processing region. The one or more first electromagnetic coils may be toroidal in shape and may at least partially encircle a central portion of the processing region. In some cases, the windings of the one or more first electromagnetic coils may be aligned perpendicular to a plane of the semiconductor substrate. In other cases, the windings of the one or more first electromagnetic coils may be slanted (e.g., not aligned perpendicular to a plane of the semiconductor substrate) to further assist in the generation of a uniform plasma above the semiconductor substrate by generating a uniform magnetic field. In some cases, generating the uniform plasma may benefit from a higher magnetic field at the edge of the semiconductor substrate to compensate for edge etch rate roll off. By manipulating the current of the first electromagnetic coils, the edge etch rate may be adjusted. Slanting the first electromagnetic coils may allow for different magnetic fields to be generated at different radius's of the semiconductor substrate.

The second coil assembly may include one or more second electromagnetic coils coupled to or embedded in a plasma screen disposed in the processing region. The one or more second electromagnetic coils may be toroidal in shape and may at least partially encircle a central portion of the processing region. The one or more second electromagnetic coils may be configured to tune the magnetic field (individually or in combination with the one or more first electromagnetic coils) on the substrate supporting surface. For example, the one or more second electromagnetic coils may enable edge tuning of the plasma by varying the current and generated B-fields in radial and vertical directions.

### Plasma Processing Assembly Example

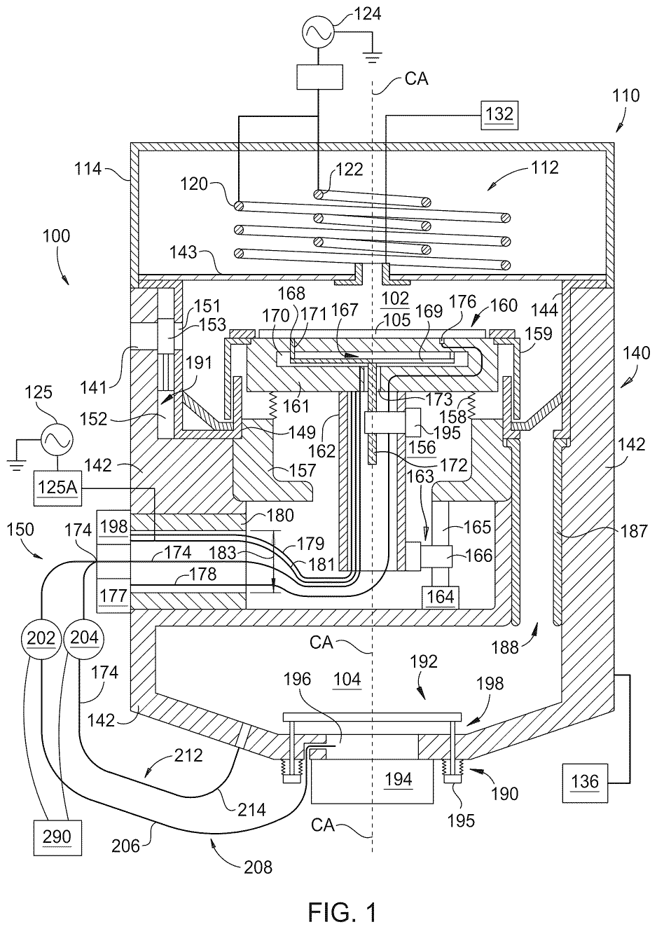

FIG. 1 is a schematic, cross-sectional view of a plasma processing assembly 100 that may be configured to practice the methods set forth herein. The plasma processing assembly 100 includes a pumping system 150 coupled to a lift pin volume. The plasma processing assembly 100 may be plasma etch chamber, a plasma enhanced chemical vapor deposition chamber, a physical vapor deposition chamber, a plasma treatment chamber, an ion implantation chamber or other suitable vacuum processing chamber, such as the Sym3® processing chamber, commercially available from Applied Materials, Inc. in Santa Clara, California.

The plasma processing assembly 100 generally includes a source module 110, a processing chamber 140, and an exhaust assembly 190, which collectively enclose a processing region 102 and an evacuation region 104. In practice, processing gases are introduced into the processing region 102 and ignited into a plasma using RF power. A substrate 105 is positioned on a substrate support assembly 160 and exposed to the plasma generated in the processing region 102 to perform a plasma process on the substrate 105, such as etching, chemical vapor deposition, physical vapor deposition, implantation, plasma annealing, plasma treating, abatement, or other plasma processes. Vacuum is maintained in the processing region 102 by exhaust assembly 190, which removes spent processing gases and byproducts from the plasma process through the evacuation region 104.

In some embodiments, the source module 110 may be an inductively coupled plasma source. The source module 110 generally includes an upper electrode 112 (or anode) isolated from and supported by the processing chamber 140 and a chamber lid assembly 114, enclosing the upper electrode 112. The upper electrode 112 may include an outer coil assembly 120 and an inner coil assembly 122 that are disposed over a dielectric window 143 of the chamber lid assembly 114. The outer coil assembly 120 and the inner coil assembly 122 may be connected to a radio frequency (RF) power source 124. A gas inlet tube 126 may be disposed along a central axis (CA) of the processing chamber 140. The gas inlet tube may be coupled with a gas source 132 to supply one or more processing gases to the processing region 102.

The processing chamber 140 includes a chamber body 142 fabricated from a conductive material resistant to processing environments. The substrate support assembly 160 is centrally disposed within the chamber body 142. The substrate support assembly is positioned to support the substrate 105 in the processing region 102 symmetrically about the central axis (CA).

The processing region 102 is accessed through a slit valve tunnel 141 disposed in the chamber body 142 that allows entry and removal of the substrate 105. The chamber assembly may include a chamber liner 144 that has a slot 151 disposed therethrough that matches the slit valve tunnel 141 to allow passage of the substrate 105 therethrough. The processing chamber 140 includes a slit valve door assembly 191 that includes an actuator 152 positioned and configured to vertically extend a slit valve door 153 to seal the slit valve tunnel 141 and slot 151 and to vertically retract the slit valve door 153 to allow access through the slit valve tunnel 141 and slot 151. Backing liners may be provided, attached to and covering, the slots of the chamber liner 144. The backing liners are also in conductive contact with the chamber liner 144 to maintain electrical and thermal contact with the chamber liner 144.

The substrate support assembly 160 generally includes lower electrode 161 (or cathode) and a hollow pedestal 162. The substrate support assembly 160 is supported by a central support member 157 disposed in the central region 156 and supported by the chamber body 142. The lower electrode 161 is coupled to an RF power source 125 through a matching network 125A and a cable (not shown) routed through the pedestal 162. When RF power is supplied to the upper electrode 112 and the lower electrode 161, an electrical field formed therebetween ignites the processing gases present in the processing region 102 into a plasma.

The central support member 157 is sealed to the chamber body 142, such as by fasteners and o-rings (not shown). The lower electrode 161 is sealed to the central support member 157, such as by a bellows. Thus, the central region 156 is sealed from the processing region 102 and may be maintained at atmospheric pressure, while the processing region 102 is maintained at vacuum conditions.

An actuation assembly 163 is positioned within the central region 156 and attached to the chamber body 142 and/or the central support member 157. The actuation assembly 163 includes an actuator 164 (e.g., motor), a lead screw 165, and a nut 166 attached to the pedestal 162. In practice, the actuator 164 rotates the lead screw 165, which, in turn raises or lowers the nut 166, and thus the pedestal 162. Since the lower electrode 161 is supported by the pedestal 162, the actuation assembly 163 provides vertical movement of the lower electrode 161 relative to the chamber body 142, the central support member 157, and the upper electrode 112. Such vertical movement of the lower electrode 161 within the processing region 102 provides a variable gap between the lower electrode 161 and the upper electrode 112, which allows increased control of the electric field formed therebetween, in turn, providing greater control of the density in the plasma formed in the processing region 102. In addition, since the substrate 105 is supported by the lower electrode 161, the gap between the substrate 105 and a showerhead plate (not shown) may also be varied, resulting in greater control of the process gas distribution across the substrate 105.

A substrate support assembly liner 159 is also provided, supported by the lower electrode 161 and overlapping the inner wall 149 of the chamber liner 144, to protect the substrate support assembly 160 and the bellows 158 from the plasma in the processing region 102. Since the substrate support assembly liner 159 is coupled to and moves vertically with the pedestal 162, the overlap between substrate support assembly liner 159 and the inner wall 149 of the chamber liner 144 is sufficient to allow the pedestal 162 to enjoy a full range of motion without the substrate support assembly liner 159 and the chamber liner 144 becoming disengaged and allowing exposure of the region below the pedestal 162 to become exposed to process gases. The substrate support assembly liner 159 may be constructed of materials similar to that of the chamber liner 144 as described above.

The substrate support assembly 160 further includes a lift pin assembly 167 to facilitate loading and unloading of the substrate 105. The lift pin assembly 167 includes lift pins 168 attached to a lift pin plate 169. The lift pin plate 169 is disposed within an opening 170 within the lower electrode 161, and the lift pins 168 extend through lift pin holes 171 disposed between the opening 170 and the processing region 102. The lift pin plate 169 is coupled to a lead screw 172 extending through an aperture 173 in the lower electrode 161 and into the hollow pedestal 162. An actuator 195 (e.g., motor) may be positioned on the pedestal 162. The actuator 195 rotates a nut, which advances or retracts the lead screw 172. The lead screw 172 is coupled to the lift pin plate 169. Thus, as the actuator 195 causes the lead screw 172 to raise or lower the lift pin plate 169, the lift pins 168 to extend or retract. Therefore, the actuator 195 allows the lift pins 168 to be extended or retracted regardless of the vertical positioning of the lower electrode 161. By providing such separate actuation of the lift pins 168, the vertical positioning of the substrate 105 can be altered separately from the vertical positioning of the lower electrode 161 allowing greater control of positioning during both loading and unloading of the substrate 105 as well as during processing of the substrate 105, for example, by lifting the substrate during processing to allow backside gas to escape from under the substrate.

The substrate support assembly 160 further includes the pumping system 150. The pumping system 150 is configured to pump any processing gases that may leak into the opening 170 via the lift pin holes 171. In certain etch applications, the processing apparatus is run with very high bias powers, which lead to the development of large RF voltages in the lower electrode 161. The high RF voltages, when combined with the high pressure in the opening 170, can lead to undesired plasma discharge (i.e., “light up) or arcing in the lower electrode 161, which can cause catastrophic failure. Conventional pumping systems provide a single pump path from either the opening 170 to the evacuation region 104, or from the opening 170 to the exhaust port 196. Because of the high bias powers used in etch applications, the pressure in the opening 170 may be modulated to minimize the formation of parasitic plasma therein.

The pumping system 150 includes a pump line 174, a first valve 202, and a second valve 204. The pump line 174 creates a pump path between the opening 170 and the first valve 202 and the second valve 204. A second pump line 206 extends between the first valve 202 and the exhaust port 196, forming a first parallel pump path 208. The first valve 202 is configurable between an open and closed state. A third pump line 214 extends between the second valve 204 and the evacuation region 104, forming a second parallel pump path 212. The second valve 204 is configurable between an open and closed state. The pumping system 150 further includes a controller 290, coupled to the first valve 202 and the second valve 204. The controller 290 is configured to control switching of the first valve 202 and the second valve 204 between an open and closed state.

The substrate support assembly 160 may also include a gas port 176 disposed therethrough and coupled to an inert gas supply 177 via a gas supply line 178. The gas supply 177 supplies an inert gas, such as helium, through the gas supply line 178 and the gas port 176 to the backside of the substrate 105 in order to help prevent processing gases from processing the backside of the substrate 105. The gas supply line 178 is also routed through the hollow pedestal 162 and out of the chamber body 142 through one of the plurality of access tubes 180.

The substrate support assembly 160 may further include one or more fluid inlet lines 179 and fluid outlet lines 181 routed from a heat exchange fluid source 198 to through one or more heat exchange channels (not shown) in the lower electrode 161 in order to provide temperature control to the lower electrode 161 during processing. The fluid inlet lines 179 and fluid outlet lines 181 are routed from the lower electrode 161 through the hollow pedestal 162 and out of the chamber body 142 through one of the plurality of access tubes 180.

One or more access tubes 180 within spokes (not shown) of the processing chamber 140. The spokes and access tubes 180 are symmetrically arranged about the central axis (CA) of the plasma processing assembly 100 in a spoke pattern as shown. In the embodiment shown, three identical access tubes 180 are disposed through the chamber body 142 into the central region 156 to facilitate supply of a plurality of tubing and cabling from outside of the chamber body 142 to the lower electrode 161. In order to facilitate vertical movement of the lower electrode 161, the opening 183 through each of the access tubes 180 is approximately equal to the vertical travel of the lower electrode 161.

In order to further facilitate cable routing to the lower electrode 161, the cable routing is divided between the plurality of access tubes 180. Thus, number and volume of cabling from outside of the chamber body 142 to the lower electrode 161 are divided between the access tubes 180 in order to minimize the size of the access tubes 180 while providing adequate clearance to facilitate the movement of the lower electrode 161.

The evacuation passages are positioned in the chamber liner 144 symmetrically about the central axis (CA). The evacuation passages 188 allow evacuation of gases from the processing region 102 through the evacuation region 104 and out of the chamber body 142 through an exhaust port 196. The exhaust port 196 is centered about the central axis (CA) of the processing chamber 140 such that the gases are evenly drawn through the evacuation passages 188. Evacuation liners 187 may be respectively positioned below each of the evacuation passages 188 in evacuation channels provided in the chamber body 142 in order to protect the chamber body 142 from processing gases during evacuation. The evacuation liners 187 may be constructed of materials similar to that of the chamber liner 144 as described above.

The exhaust assembly 190 is positioned adjacent the evacuation region 104 at the bottom of the chamber body 142. The exhaust assembly may include a throttle valve 192 coupled to a vacuum pump 194. The throttle valve 192 may be a poppet style valve used in conjunction with the vacuum pump 194 to control the vacuum conditions within the processing region 102 by symmetrically drawing exhaust gases from the processing region 102 through the evacuation passages 188 and out of the chamber through the centrally located exhaust port 196, further providing greater control of the plasma conditions in the processing region 102. A poppet style valve, as shown in FIG. 1, provides a uniform, 360 degree gap through which evacuation gases are drawn through the exhaust port 196. In contrast, conventional damper-style throttle valves provide a non-uniform gap for flow of evacuation gases. For example, when the damper-style valve opens, one side of the valve draws more gas than the other side of the valve. Thus, the poppet style throttle valve has less effect on skewing gas conductance than the traditional damper-style throttle valve conventionally used in plasma processing chambers.

The plasma processing assembly 100 further includes a system controller 136. The system controller 136 is configured to aid in controlling the process parameters of the plasma processing assembly 100. For example, the system controller 136 may be configured to carry out the process recipe uploaded by an end user for the substrate to be processed. System controller 136 may be in communication with controller 290, such that efficient control of the process parameters, as well as the pumping system 150 may be achieved. In some embodiments, system controller 136 and controller 290 may be combined into a single controller configured to manage both the process parameters and the pumping system 150.

### Field Generation System Examples

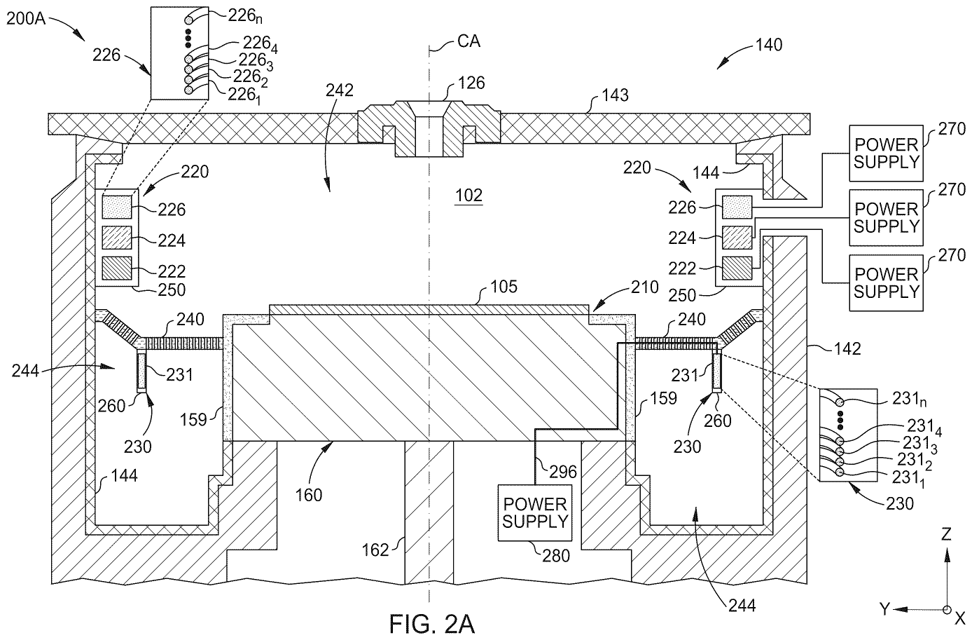

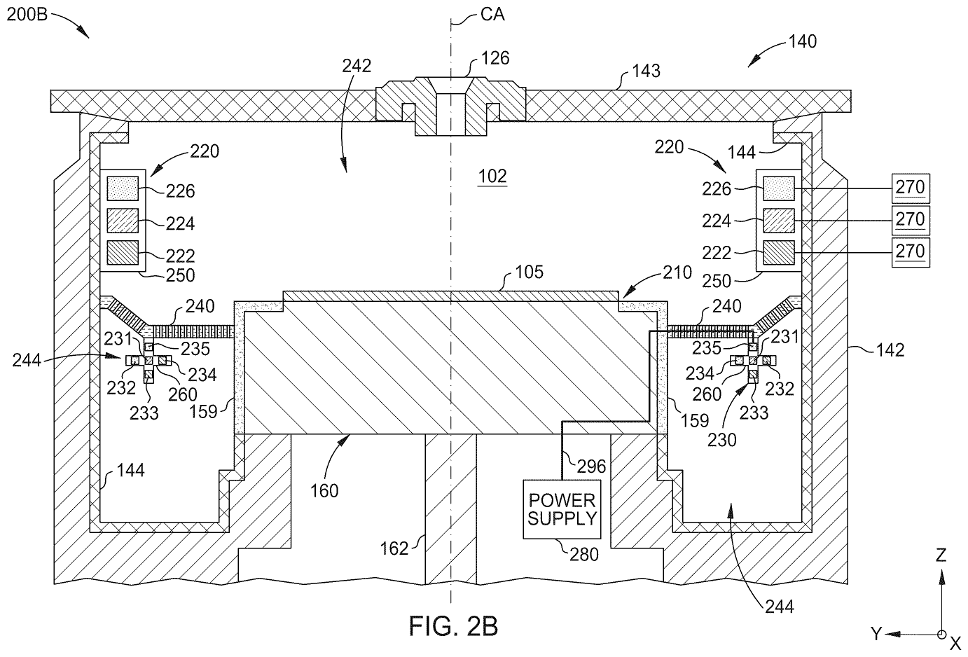

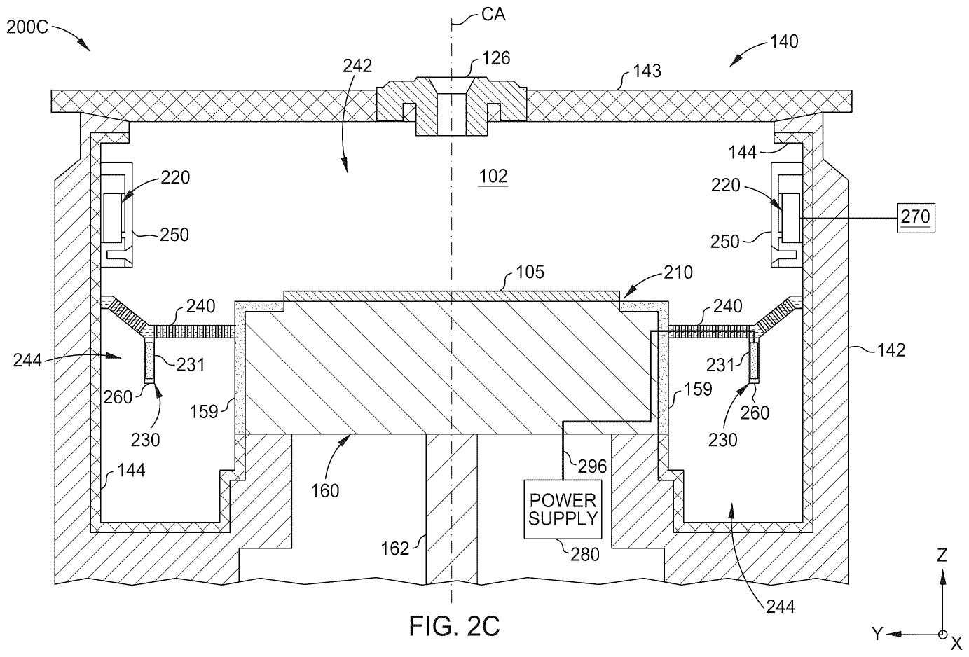

FIG. 2A-2C are simplified schematic side cross-sectional views of plasma processing assemblies 200A, 200B, 200C that include field generation systems, according to one or more embodiments, in accordance with certain embodiments of the present disclosure. The plasma processing assemblies 200A, 200B, 200C may each include the processing chamber 140, the chamber body 142, the dielectric window 143, the chamber liner 144, the gas inlet tube 126, the substrate support assembly 160, the substrate support assembly liner 159, the processing region 102, and the pedestal 162. As illustrated, the substrate support assembly 160 may be disposed in the processing region 102 and may include a substrate supporting surface 210 configured to support the substrate 105. FIGS. 2A-2C, 3A-3D, and 4A-4E each include an X-Y-Z coordinate system to help illustrate the alignment of various coils included in the field generation systems included in each of the plasma processing assemblies of FIGS. 2A-2C, 3A-3D, and 4A-4E.

The field generation system of the plasma processing assemblies 200A, 200B, 200C may include a first electromagnetic coil assembly 220 (hereinafter referred to simply as “first coil assembly 220”) disposed within the processing region 102. The first coil assembly 220 may include one or more first coils 222, 224, 226. For example, the number of first coils 222, 224, 226 may be three (as illustrated in FIGS. 2A-2C). It is to be understood that any number of coils may be included in the first coil assembly 220, and that each of the one or more first coils 222, 224, 226 could be wound in any manner (e.g., vertically, horizontally, at an angle, etc.). In some embodiments, the one or more first coils 222, 224, 226 may be concentrically wound coils that at least partially circle the processing region 102. In some examples, each of the one or more first coils 222, 224, 226 may be concentrically wound by including one or more circumferential windings wound in a circular orientation that forms a ring around the substrate support assembly 160. In some cases, at least one of the one or more first coils 222, 224, 226 may be a solenoid type coil, such as a helically wound coil whose length is longer than its diameter. Any of the one or more first coils 222, 224, 226 may be a coil which includes multiple coil turns (or loops). For example, coil 226 may include one or more coil turns 226₁, 226₂, 226₃, 226₄, 226ₙ, where n represents the coil number. Although five coil turns 226₁, 226₂, 226₃, 226₄, 226ₙ are illustrated in FIG. 2A, it is to be understood that any number of coil turns may be included, and that the coils may be tightly wound to efficiently generate magnetic fields.

The windings of the one or more first coils 222, 224, 226 may be aligned in a vertical direction (i.e., the Z-direction), such that one or more first coils 222, 224, 226 (and their respective windings) are aligned perpendicular to a plane of the substrate supporting surface 210 (e.g., X-Y-plane), as illustrated in FIGS. 2A-2C. The one or more first coils 222, 224, 226 may (i) be wound in different directions relative to the process chamber's central axis (CA) (e.g., positive and negative current directions), (ii) have different numbers of turns, and/or (iii) have different coil core sizes. In this manner, each of the first coils 222, 224, 226 may have varying current carrying capacities. In some cases, one or more of the one or more first coils 222, 224, 226 may have between 10 and 500 turns. For example, one or more of the one or more first coils 222, 224, 226 may have around 100 turns.

The first coil assembly 220 may be coupled to the chamber liner 144, as illustrated in FIGS. 2A-2C. For example, the first coil assembly 220 (including the one or more first coils 222, 224, 226) may be follow the contours of the chamber liner 144 and be wound such that the diameter of the windings have a diameter that is greater than or equal to the diameter of the substrate support assembly 160.

The field generation system of the plasma processing assemblies 200A, 200B, 200C may include a second electromagnetic coil assembly 230 (hereinafter referred to simply as “second coil assembly 230”) disposed within the processing region 102. Although both the first coil assembly 220 and a second coil assembly 230 are illustrated in FIGS. 2A-2C, it is to be understood that only one or both of the first coil assembly 220 and the second coil assembly 230 may be included in a field generation system provided within the plasma processing assembly. The second coil assembly 230 may include one or more second coils 231, 232, 233, 234, and 235. For example, the number of second coils 231, 232, 233, 234, and 235 may include one coil (as illustrated in FIGS. 2A and 2C) or five coils (as illustrated in FIG. 2B). It is to be understood that any number of coils may be included in the second coils 231, 232, 233, 234, and 235, and that each of the one or more second coils 231, 232, 233, 234, and 235 could be wound in any manner (e.g., vertically, horizontally, at an angle, etc.). In some embodiments, the one or more second coils 231, 232, 233, 234, and 235 may be concentrically wound coils that at least partially encircle a central axis (CA) of the processing region 102. For example, the one or more second coils 231, 232, 233, 234, and 235 may include circumferential windings and be wound in a circular orientation that forms a ring or toroid shape around the substrate support assembly 160. At least one of the one or more second coils 231, 232, 233, 234, and 235 may be a solenoid type coil. Any of the second coils 231, 232, 233, 234, and 235 may be a coil which includes multiple coil turns (or loops). For example, coil 231 may include one or more coil turns 231₁, 231₂, 231₃, 231₄, 231ₙ, where n represents the letter corresponding to the coil number. Although three coil turns 231₁, 231₂, 231₃, 231₄, 231ₙ are illustrated in FIG. 2A, it is to be understood that any number of coil turns may be included, and that the coils may be tightly wound to efficiently generate magnetic fields.

The windings of the one or more second coils 231, 232, 233, 234, and 235 may be aligned in a vertical direction (i.e., the Z-direction), such that one or more second coils 231, 232, 233, 234, and 235 (and their respective windings) are aligned perpendicular to a plane of the substrate supporting surface 210 (e.g., the X-Y-plane), as illustrated in FIGS. 2A-2C. The one or more second coils 231, 232, 233, 234, and 235 may (i) be wound in different directions relative to the central axis (CA) (e.g., positive and negative current directions), (ii) have different numbers of turns, and/or (iii) have different core sizes. In this manner, each of the second coils 231, 232, 233, 234, and 235 may have varying current carrying capacities. In some cases, one or more of the one or more second coils 231, 232, 233, 234, and 235 may have between 10 and 500 turns. For example, one or more of the one or more first coils 222, 224, 226 may have around 100 turns.

The plasma processing assemblies 200A, 200B, 200C may include a plasma screen 240 that at least partially circles the substrate support assembly 160. The plasma screen 240 may be disposed within the processing region 102 and may form a first region 242 of the processing region and a second region 244 of the processing region. The first coil assembly 220 may be disposed in the first region 242, whereas the second coil assembly 230 may be disposed in the second region 244, as illustrated. The plasma screen 240 may be grounded through the chamber body 142 (both the chamber body 142 in the first region and the chamber body 142 in the second region) and the substrate supporting surface 210. In some cases, the chamber body 142 may include one or more radio frequency (RF) gaskets for grounding the plasma screen 240 to a grounded surface within the plasma processing assemblies. One or more of the RF gaskets may be located, for example, above the plasma screen (e.g., in the first region 242), and/or one or more of the RF gaskets may be located below the plasma screen (e.g., in the second region 244).

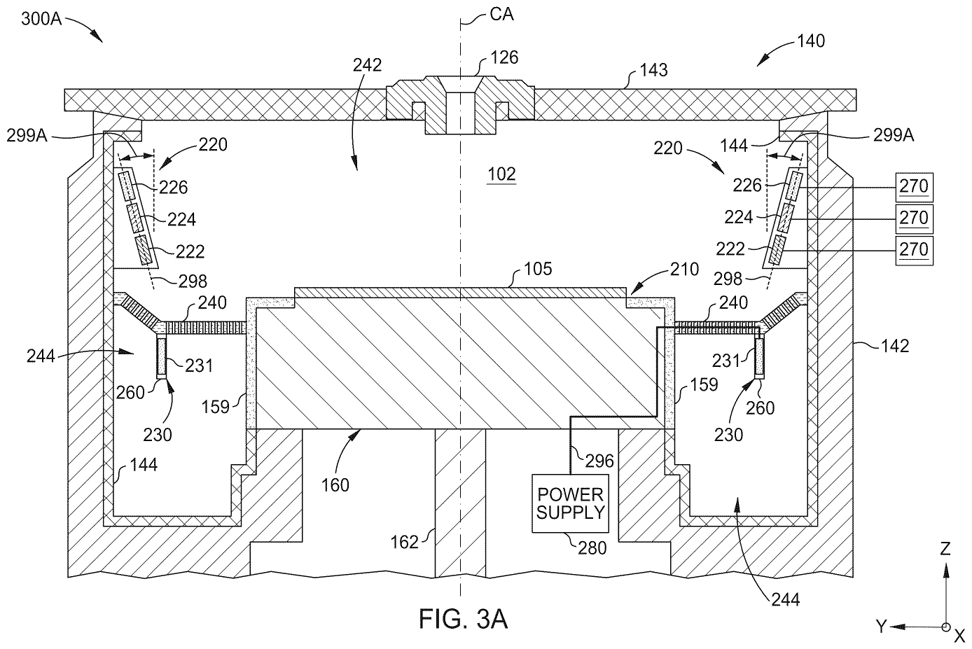

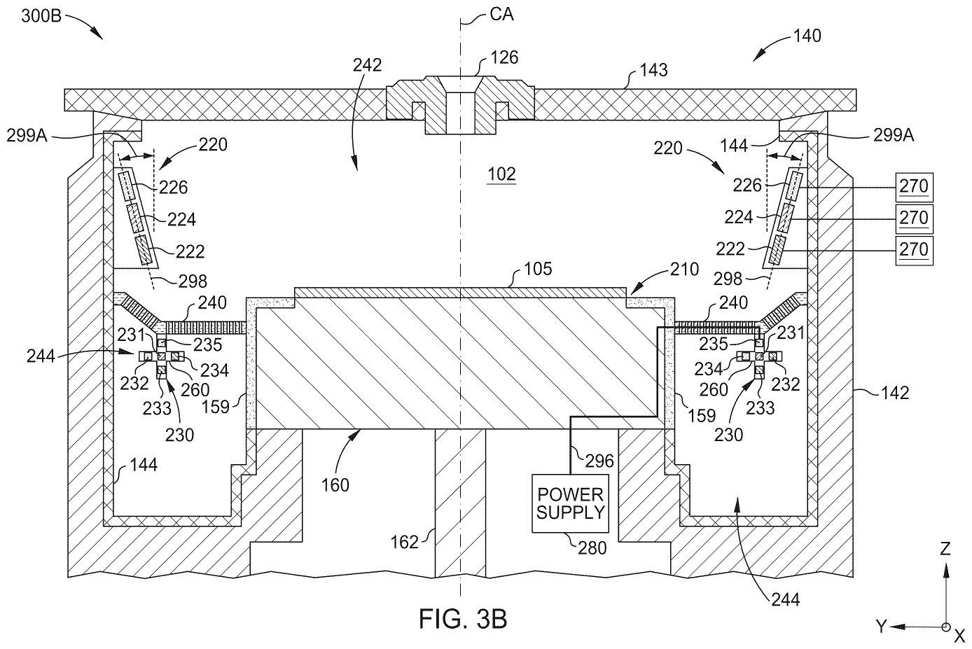

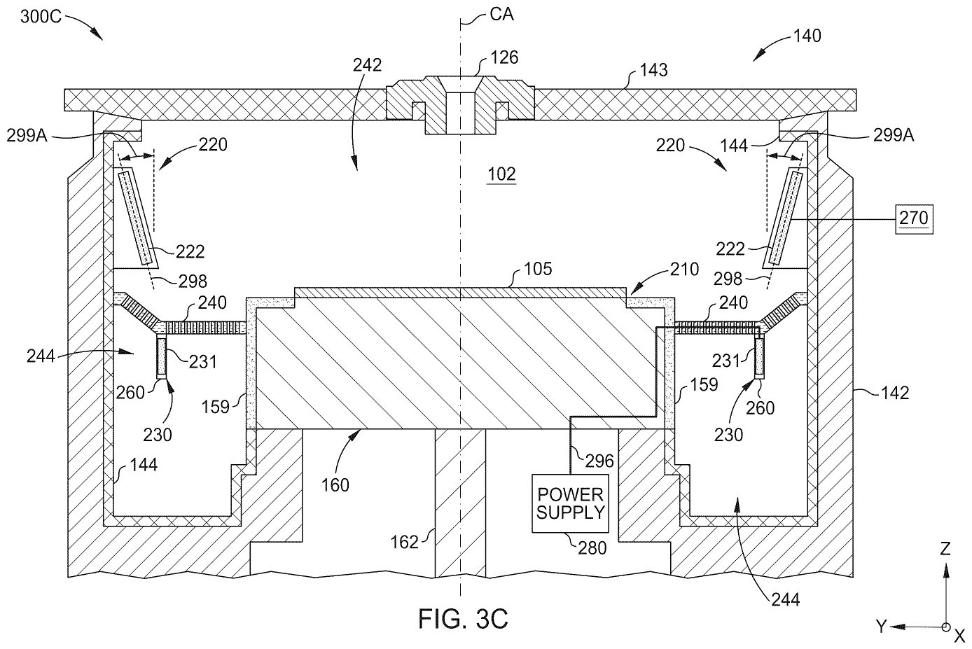

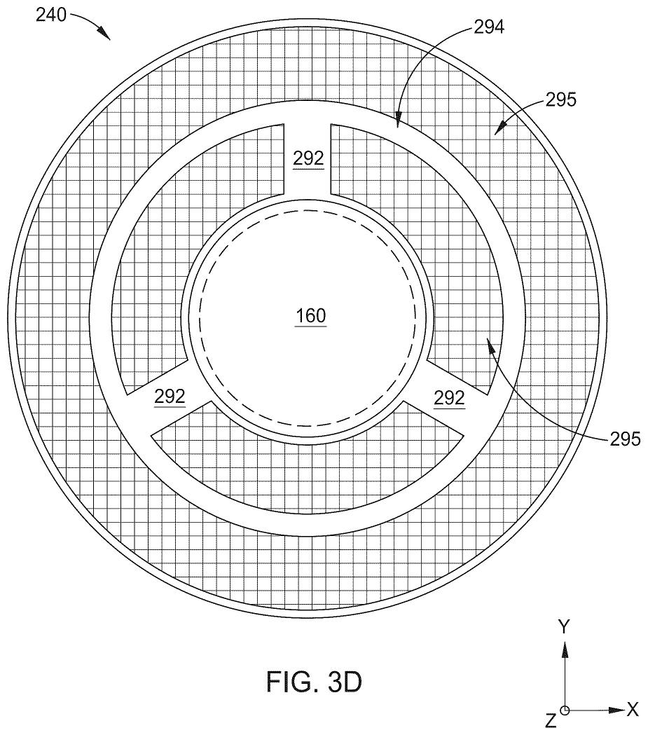

In some embodiments, the second coil assembly 230 may be coupled to the plasma screen 240, as illustrated in FIGS. 2A-2C and 3A-3C. It is to be understood that the second coil assembly 230 may be coupled to any portion of the plasma screen 240. For example, the second coil assembly 230 may be coupled to the plasma screen adjacent to the substrate supporting surface 210, adjacent to the chamber body 142 and the chamber liner 144, or anywhere in between. In some cases, a first portion of the plasma screen 240 may be parallel to the plane of the substrate supporting surface 210 (e.g., the X-Y-plane), whereas a second portion may be slanted relative to the plane of the substrate supporting surface 210, as illustrated in FIGS. 2A-2C and 3A-3C.

The plasma processing assemblies 200A, 200B, 200C may include a first housing 250 coupled to the chamber liner 144 and configured to house (e.g., enclose) the first coil assembly 220 in the first region 242. In this manner, the first coil assembly 220 may be isolated from gases and/or process by-products in the processing region 102. In some cases, the first housing 250 may be implemented by a cover structure as illustrated in FIG. 2C, where the cover structure is coated to prevent damage to the first coil assembly 220. The first housing 250 may include or be made from, for example, aluminum and be anodized and/or coated to prevent damage to the first coil assembly 220. In another example, the first housing 250 may include or be made from ceramic.

The plasma processing assemblies 200A, 200B, 200C may include a second housing 260 coupled to the plasma screen 240 and configured to house (e.g., surround) the second coil assembly 230 in the second region 244. In this manner, the second coil assembly 230 may be isolated from gases and/or process by-products in the processing region 102. The second housing 260 may be rectangular (e.g., as illustrated in FIGS. 2A, 2C, 3A, and 3C), cross-shaped (e.g., as illustrated in FIGS. 2B and 3B), square, circular, or any other shape configured to house the second coil assembly 230. The second housing 260 may include or be formed from, for example, aluminum and be anodized and/or coated to prevent damage to the second coil assembly 230. In another example, the second housing 260 may include or be made from ceramic material, such as alumina, aluminum nitride, or quartz. The geometry of the plasma screen 240 (as well as the geometry of the plasma screen 440, which is described below) may dictate the geometry of the one or more second coils 231, 232, 233, 234, and 235 in the second coil assembly 230. The geometry of the one or more second coils 231, 232, 233, 234, and 235 impacts the generation of the plasma and the magnitude of the generated magnetic field at various locations in the plasma processing assemblies 200A, 200B, 200C and on a substrate on the substrate supporting surface 210.

The plasma processing assemblies 200A, 200B, 200C may include one or more first power supply circuits 270 (labeled “POWER SUPPLY”) coupled to the first coil assembly 220 (e.g., through one or more atmosphere openings in the chamber body 142 and the chamber liner 144) and configured to drive the one or more first coils 222, 224, 226. The one or more first power supply circuits 270 may be continuous direct current (DC) and/or low frequency alternating current (AC) power supply circuits. In some cases, each of the one or more first coils 222, 224, 226, may be coupled to a separate first power supply circuit 270, such that each first power supply circuit 270 is configured to bias (e.g., drive) one of the first coils 222, 224, 226. In other cases, multiple coils of the first coils 222, 224, 226 may be biased by a single first power supply circuit 270.

The plasma processing assemblies 200A, 200B, 200C may include one or more second power supply circuits 280 (labeled “POWER SUPPLY”) coupled to the second coil assembly and configured to drive the one or more second coils 231, 232, 233, 234, 235. The one or more second power supply circuits 280 may be continuous DC and/or low frequency AC power supply circuits. In some cases, each of the one or more second coils 231, 232, 233, 234, 235, may be coupled to a separate second power supply circuit 280, such that each second power supply circuit 280 is configured to bias (e.g., drive) one of the second coils 231, 232, 233, 234, 235. In other cases, multiple coils of the second coils 231, 232, 233, 234, 235 may be biased by a single second power supply circuit 280.

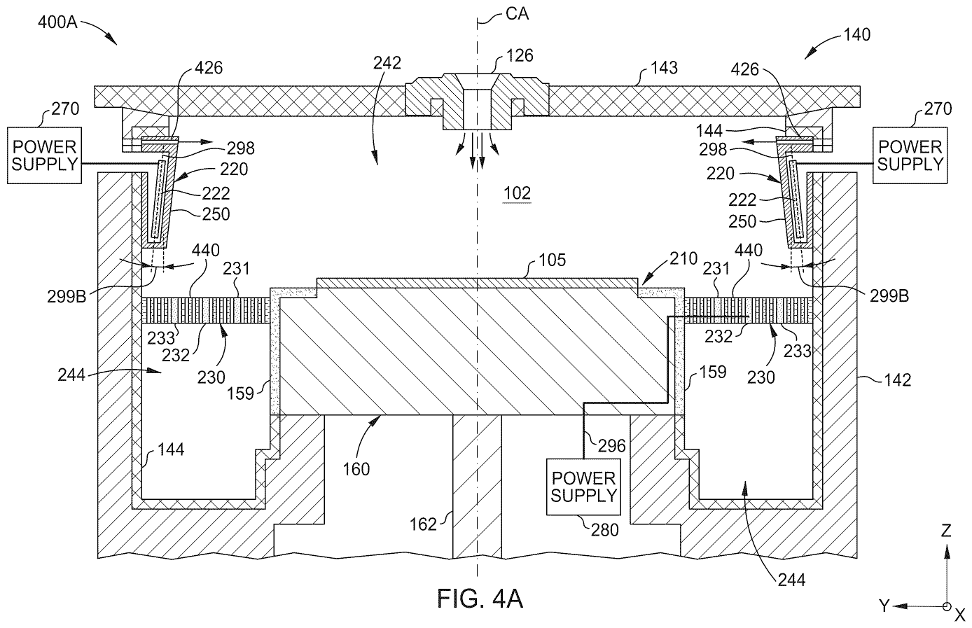

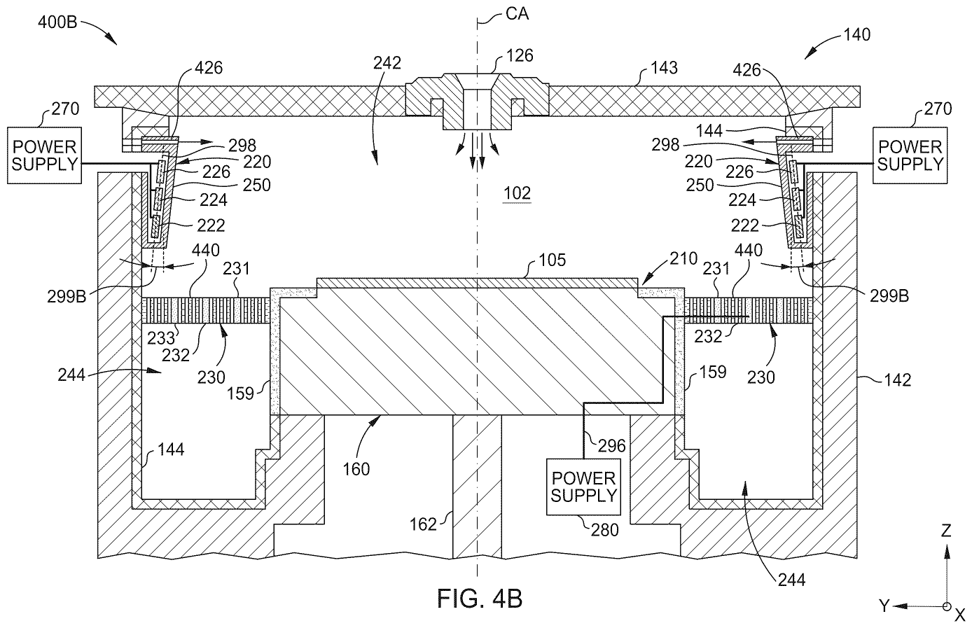

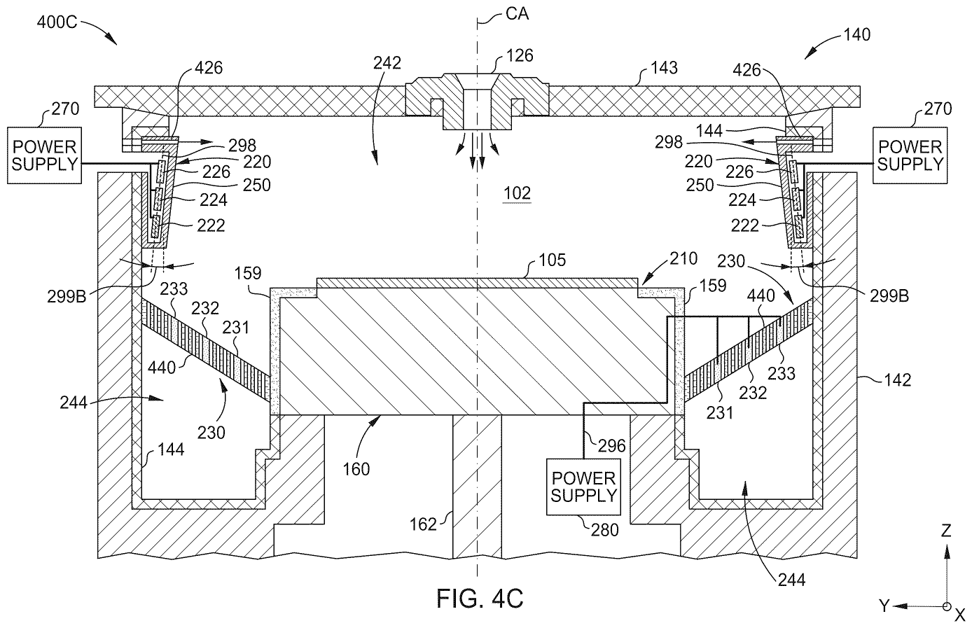

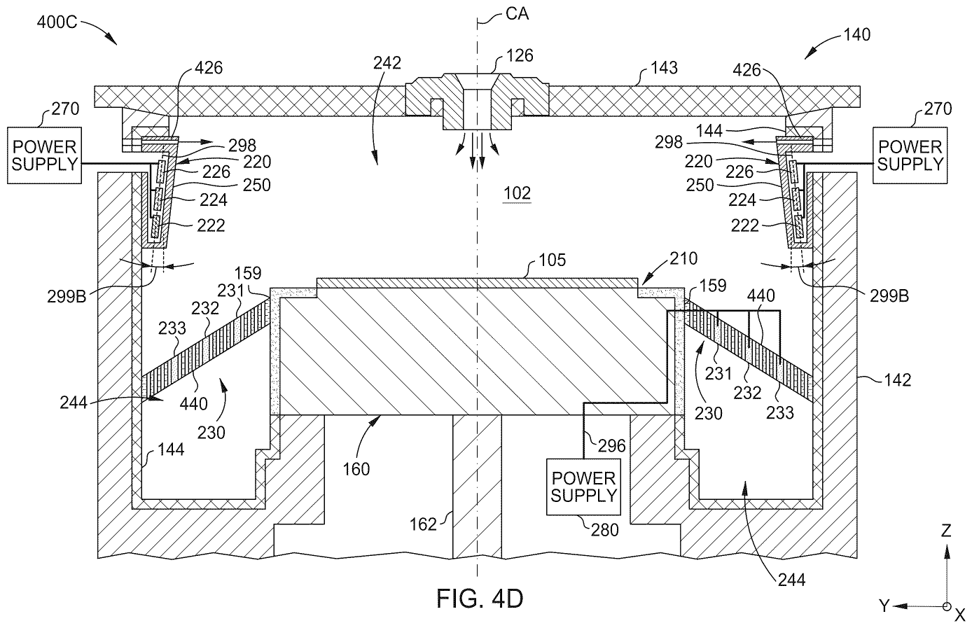

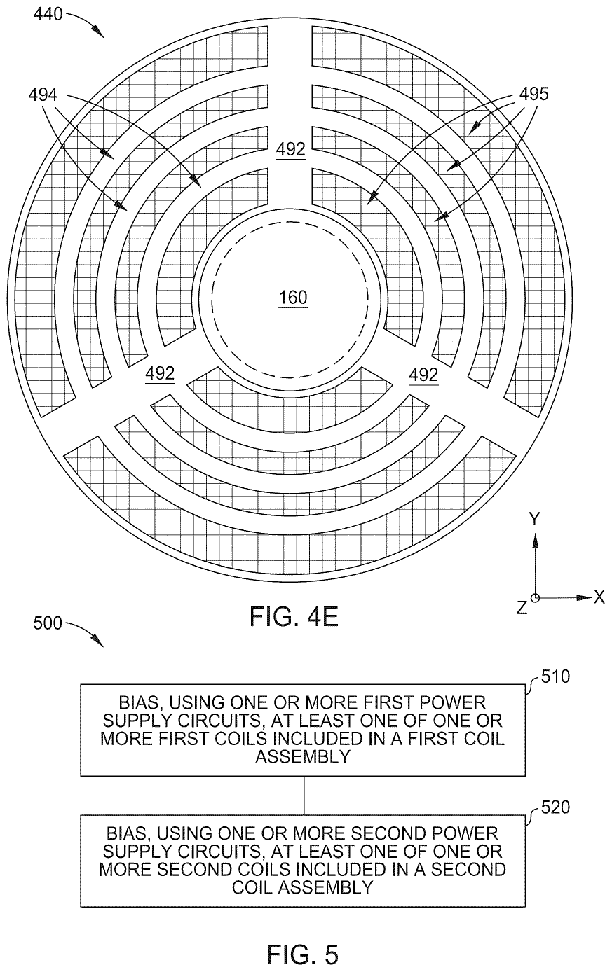

FIG. 3A-3C are simplified schematic side cross-sectional views of plasma processing assemblies 300A, 300B, 300C that include field generation systems with slanted coils, according to one or more embodiments, in accordance with certain embodiments of the present disclosure. The plasma processing assemblies 300A, 300B, 300C may be similar to plasma processing assemblies 200A, 200B, 200C, except that the first coil assembly 220 may be aligned in a slanted direction 298, such that the windings of the one or more first coils 222, 224, 226 are at an angle (e.g., slanted) to a direction (e.g., the central axis (CA)) that is perpendicular to a plane of the substrate supporting surface 210 (e.g., the X-Y-plane), as illustrated in FIGS. 3A-3C. It is to be understood that the slanted direction 298 could be at any angle relative to the central axis (CA) (e.g., Z-axis) (e.g., as shown, for example, in FIGS. 3A-3C and 4A-4D). In one example, as shown in FIGS. 3A-3C, the slanted direction 298 is at an angle, referred to herein as an outward tilt angle 299A, of between 1° and 30° relative to the central axis (CA) (e.g., parallel to the Z-axis), such as at an angle of between 1° and 20°, or at an angle of between 1° and 15°, as measured in a clockwise direction from the central axis (CA).

FIG. 3D is a schematic top view of the plasma screen 240 included in the plasma processing assemblies 200A, 200B, 200C, 300A, 300B, 300C of FIGS. 2A-2C and 3A-3C, respectively, in accordance with certain embodiments of the present disclosure. The plasma screen 240 may encircle the substrate support assembly 160, as illustrated. The plasma screen 240 may include one or more opening regions 295 that include openings (e.g., perforations) that form a path between the first region 242 and a pump (e.g., part or all of pumping system 150) disposed in the second region 244. The plasma screen 240 may also include one or more wiring fins 292 and one or more coil regions 294, which are used to support the one or more second coils 231, 232, 233, 234, and 235. Therefore, in one configuration, the one or more second coils 231, 232, 233, 234, and 235 may be coupled to and disposed below the one or more coil regions 294, such that the one or more second coils 231, 232, 233, 234, 235 are disposed in the second region 244 under the plasma screen 240. In some embodiments, the plasma screen 240 is positioned below the substrate supporting surface 210. The wiring fins 292 may be configured to form a path for one or more cables 296 to connect the second coil assembly 230 to the power supply circuit(s) 280. The cables 296 may be isolated to prevent exposure to gases or process by-products in the processing region 102. In this manner, the plasma screen may enable second coil assembly 230 to be driven while ensuring proper gas conductance in the processing chamber 140 through the openings in the plasma screen, as illustrated in FIG. 3D. The openings in the plasma screen may be of various shapes, such as a round hole, a square hole, an oblong slot, or other shapes to maximize the chamber conductance and by-product pump out.

FIG. 4A-4D are simplified schematic side cross-sectional views of plasma processing assemblies 400A, 400B, 400C, 400D that include field generation systems with coils embedded in a plasma screen, according to one or more embodiments, in accordance with certain embodiments of the present disclosure. The plasma processing assemblies 400A, 400B, 400C, 400D may be similar to plasma processing assemblies 200A, 200B, 200C, except that the second coil assembly 230 may be embedded within a plasma screen 440 (which may be implemented and/or referred to as a baffle screen or ring), as illustrated in FIGS. 4A-4D. In this manner, the one or more second coils 231, 232, 233, 234, and 235 may be arranged concentrically in the plasma screen 440, with or without gaps between adjacent coils. Any of the plasma processing assemblies described herein may also include one or more secondary gas inlets 426, as illustrated in FIGS. 4A-4D. It is to be understood that any described herein with respect to the plasma screen 440 may also be applied to the plasmas screen 240, and vice versa.

The plasma processing assemblies 400A, 400B, 400C, 400D may also separately include a first coil assembly 220 configuration that is aligned in a slanted direction 298 that is at an angle to the central axis (CA) that is configured to include an inward tilt angle 299B relative to central axis (CA), as illustrated in FIGS. 4A-4D, versus the outward tilt angle 299A relative to central axis (CA), as illustrated in FIGS. 3A-3C. The inward tilt angle 299B can be at an angle of between 1° and 30° relative to the central axis (CA) (e.g., parallel to the Z-axis), such as at an angle of between 1° and 20°, or at an angle of between 1° and 15°, as measured in a clockwise direction from the central axis (CA).

In embodiments where the second coil assembly 230 is embedded in the plasma screen 440, the plasma screen 440 may effectively serve as the housing of the second coil assembly 230 and isolate the one or more second coils 231, 232, 233, 234, and 235 from the gases and/or process by-products in the processing region 102. In some cases, the entirety of the plasma screen 440 may be parallel to the plane of the substrate supporting surface 210 (e.g., the X-Y-plane), as illustrated in FIGS. 4A and 4B. In other cases, the plasma screen 440 may be angled (e.g., slanted) in any direction relative to the plane of the substrate supporting surface 210 (e.g., the Y-axis), as illustrated in FIGS. 4C and 4D. In some cases, the plasma screen 440 may be slanted such that the vertical high side of the plasma screen is adjacent the substrate supporting surface (as shown in FIG. 4D), whereas in other cases, the plasma screen 440 may be slanted such that the vertical low side of the plasma screen is adjacent the substrate supporting surface (as shown in FIG. 4C). When the coils housed in the plasma screen 440 are closer to the edge of a substrate on the substrate supporting surface 210, current demands may be reduced and current efficiency may be improved, as the magnetic field strength generated from the coils drops off as the distance to the coil increases. In some embodiments, the plasma screen 440 is positioned below the substrate supporting surface 210.

FIG. 4E is a schematic top view of the plasma screen 440 included in a plasma processing assemblies 400A, 400B, 400C, 400D of FIGS. 4A-D, accordance with certain embodiments of the present disclosure. The plasma screen 440 may include one or more opening regions 495 that include openings (e.g., perforations). The plasma screen 440 may also include one or more wiring fins 492 and one or more coil regions 494, which are used to support the one or more second coils 231, 232, 233, 234, and 235. The one or more second coils 231, 232, 233, 234, and 235 may be disposed in the one or more coil regions 494, such that the one or more second coils 231, 232, 233, 234, 235 are disposed in the second region 244. Adjacent regions of the one or more coil regions 494 may be separated by the openings of the plasma screen 440, as illustrated. The wiring fins 492 may be configured to form a path for the cables 296 to connect the second coil assembly 230 to the power supply circuit(s) 280. In this manner, the plasma screen 440 may enable second coil assembly 230 to be driven while ensuring proper conductance in the plasma processing assembly through the openings in the plasma screen (as illustrated in FIG. 4E).

Embodiments described herein may be used to eliminate (or at least reduce) the effects of plasma non-uniformity on a semiconductor substrate and enhance plasma processing by controlling the magnetic fields generated from a field generation system. In this manner, various characteristics of the generated plasma, such as plasma uniformity, plasma density and shape, local and global tilt, IED, EED, and other useful parameters, may be manipulated. For example, the placement of the one or more first coils 222, 224, 226 of the first coil assembly 220 above the substrate supporting surface 210 (e.g., in the first region 242) and the manipulation of the direction of the windings (e.g., positive or negative current direction as controlled by the applied bias of the first power supply circuit(s) 270), the number of turns, and the core size of the one or more first coils 222, 224, 226 may be controlled. In this manner, the one or more first coils 222, 224, 226 may enable improved coupling and plasma confinement for enhanced plasma uniformity and tuning. In some cases, one or more first coils 222, 224, 226 may be aligned in the slanted direction 298, such that the windings of the one or more first coils 222, 224, 226 are at an angle 299A, 299B to a direction (e.g., the Z-axis) that is perpendicular to a plane of the substrate supporting surface 210 (e.g., the X-Y-plane) to further control the magnetic field. For example, the slanted direction 298 of the one or more first coils 222, 224, 226 may enable the density and confinement of the plasma in the processing region 102 closer to the substrate 105 may be controlled differently than the density and confinement of the plasma further away from the substrate 105 (e.g., in the positive Z-direction), depending on the desired plasma processing.

Additionally, the placement of the one or more second coils 231, 232, 233, 234, and 235 below the substrate supporting surface 210 (e.g., in the second region 244) and on or near the plasma screen 240, 440 and the manipulation of the direction of the windings (e.g., positive or negative current direction as controlled by the applied bias of the second power supply circuit(s) 280), the number of turns, and the core size of the one or more second coils 231, 232, 233, 234, and 235 may be controlled. In this manner, the one or more second coils 231, 232, 233, 234, and 235 may enable radial tuning around the substrate supporting surface 210 by varying the current and generated B-fields and plasma confinement, without negatively impacting the conductance of the plasma processing assembly.

Embodiments described herein may involve utilizing the combination of the one or more first coils 222, 224, 226 (which may be slanted and/or perpendicular relative to the Z-axis) and the one or more second coils 231, 232, 233, 234 (which may be slanted and/or perpendicular relative to the Z-axis) to assist in generating different desired magnetic fields at various locations in the plasma processing assemblies to control the plasma on a substrate on a substrate supporting surface during plasma processing. It is to be understood that any of configurations described herein for the first coils 222, 224, 226 and any of configurations described herein for the second coils 231, 232, 233, 234 may be combined in any plasma processing assembly.

### Processing Sequence Examples

FIG. 5 is a flow diagram depicting example operations 500 for processing a semiconductor substrate, according to one or more of the embodiments described herein. The operations 500 and the other operations described herein may be performed by a system controller (e.g., system controller 136 of FIG. 1) included in a plasma processing assembly (e.g., plasma processing assemblies 200A, 200B, 200C, 300A, 300B, 300C, 400A, 400B, 400C, 400D) that includes a field generation system. The system controller may include memory and one or more processors coupled to the memory. The one or more processors may be configured, individually or collectively, to perform the operations 500 and any other operations described herein.

Before the operations 500, a plasma may be formed within the processing region (e.g., processing region 102) of the plasmas processing assembly. In some embodiments, a plasma may be generated in the processing region using a capacitively-coupled-plasma (CCP) source. In other embodiments, a plasma may alternately be generated in the processing region by an inductively coupled plasma (ICP) source. The plasma may be formed by the delivery of sufficient power to one or more of the outer coil assembly 120 and the inner coil assembly 122, or by use of an auxiliary source that is configured to generate the plasma in the processing region. In one example, the auxiliary source includes a CCP source electrode that is biased by a RF source that provides an RF signal from an RF waveform generator. In some cases, the one or more coils first coils and the one or more second coils described herein may be used in conjunction with the ICP plasma.

The operations 500 include, at block 510, biasing, using one or more first power supply circuits (e.g., power supply circuit(s) 270), at least one of one or more first coils (coils 222, 224, 226) included in a first coil assembly (e.g., first coil assembly 220). It is to be understood that any number of one or more first coils may be biased. For example, all of the one or more first coils may be biased simultaneously, a portion of the one or more first coils may be biased, or none of the first coils may be biased. In some embodiments, the first coil assembly may be coupled to a chamber liner (e.g., chamber liner 144) included in the plasma processing assembly.

The operations 500 include, at block 520, biasing, using one or more second power supply circuits (e.g., power supply circuit(s) 280), at least one of one or more second coils (e.g., coil(s) 231, 232, 233, 234, 235) included in a second coil assembly (e.g., second coil assembly 230). It is to be understood that any number of one or more first coils may be biased. For example, all of the one or more second coils may be biased simultaneously, a portion of the one or more second coils may be biased, or none of the second coils may be biased. In some embodiments, the second coil assembly may be coupled to a plasma screen (e.g., plasma screen 240, 440), and the plasma screen may include one or more openings (e.g., perforations in the one or more opening regions 295, 495). In other embodiments, the second coil assembly may be embedded in the plasma screen, and the plasma screen may include one or more openings (e.g., perforations in the one or more opening regions 295, 495).

### Additional Considerations

In the above details are set forth by way of example to facilitate an understanding of the disclosed subject matter. It should be apparent to a person of ordinary skill in the field, however, that the disclosed implementations are exemplary and not exhaustive of all possible implementations. Thus, it should be understood that reference to the described examples is not intended to limit the scope of the disclosure. Any alterations and further modifications to the described devices, instruments, methods, and any further application of the principles of the present disclosure are fully contemplated as would normally occur to one skilled in the art to which the disclosure relates. In particular, it is fully contemplated that the features, components, and/or steps described with respect to one implementation may be combined with the features, components, and/or steps described with respect to other implementations of the present disclosure. As used herein, the term “about” may refer to a +/−10% variation from the nominal value. It is to be understood that such a variation can be included in any value provided herein.

As used herein, “a processor,” “at least one processor” or “one or more processors” generally refers to a single processor configured to perform one or multiple operations or multiple processors configured to collectively perform one or more operations. In the case of multiple processors, performance of the one or more operations could be divided amongst different processors, though one processor may perform multiple operations, and multiple processors could collectively perform a single operation. Similarly, “a memory,” “at least one memory” or “one or more memories” generally refers to a single memory configured to store data and/or instructions, multiple memories configured to collectively store data and/or instructions.

As used herein, a phrase referring to “at least one of” or “one or more of” a list of items refers to any combination of those items, including single members. As an example, “at least one of: a, b, or c” is intended to cover: a, b, c, a-b, a-c, b-c, and a-b-c, as well as any combination with multiples of the same element (e.g., a-a, a-a-a, a-a-b, a-a-c, a-b-b, a-c-c, b-b, b-b-b, b-b-c, c-c, and c-c-c or any other ordering of a, b, and c).

The methods disclosed herein comprise one or more steps or actions for achieving the described method. The method steps and/or actions may be interchanged with one another without departing from the scope of the claims. In other words, unless a specific order of steps or actions is specified, the order and/or use of specific steps and/or actions may be modified without departing from the scope of the claims.

The term “coupled” is used herein to refer to the direct or indirect coupling between two objects. For example, if object A physically touches object B and object B touches object C, then objects A and C may still be considered coupled to one another—even if objects A and C do not directly physically touch each other. For instance, a first object may be coupled to a second object even though the first object is never directly physically in contact with the second object.

While the foregoing is directed to embodiments of the present disclosure, other and further embodiments of the disclosure may be devised without departing from the basic scope thereof, and the scope thereof is determined by the claims that follow.

What is claimed is:

1. A plasma processing assembly comprising:
a processing chamber including a processing region;
a plasma screen disposed within the processing region that forms a first region of the processing region and a second region of the processing region;
a substrate support assembly disposed within the processing region, the substrate support assembly comprising a substrate supporting surface; and
a field generation system comprising:
a first coil assembly comprising one or more first coils that at least partially encircle the processing region, wherein windings of the one or more first coils are aligned in a first direction and wherein the first coil assembly is disposed inside the first region; and
a second coil assembly comprising one or more second coils that at least partially encircle the processing region, wherein the second coil assembly is disposed inside the second region.

2. The plasma processing assembly of claim 1, wherein the substrate support assembly comprises a central axis that is aligned perpendicular to the substrate supporting surface, and the first direction is positioned at an angle relative to the central axis.

3. The plasma processing assembly of claim 1, wherein
the second coil assembly is coupled to the plasma screen, and
the plasma screen comprises one or more openings.

4. The plasma processing assembly of claim 3, wherein the second coil assembly is embedded in the plasma screen.

5. The plasma processing assembly of claim 3, wherein the first direction is at an angle to a second direction that is perpendicular to a plane of the substrate supporting surface.

6. The plasma processing assembly of claim 1, wherein at least one of the one or more first coils comprises a concentrically wound coil.

7. The plasma processing assembly of claim 1, wherein at least one of the one or more second coils comprises a concentrically wound coil.

8. The plasma processing assembly of claim 1, wherein the one or more first coils comprise at least two coils, and wherein at least one of:
the at least two coils are wound in different directions;
the at least two coils have different numbers of turns; or
the at least two coils have different core sizes.

9. The plasma processing assembly of claim 1, wherein the one or more second coils comprise at least two coils, and wherein at least one of:
the at least two coils are wound in different directions;
the at least two coils have different numbers of turns; or
the at least two coils have different core sizes.

10. The plasma processing assembly of claim 1, further comprising:
a first housing configured to surround the first coil assembly in the first region; and
a second housing configured to surround the second coil assembly in the second region.

11. The plasma processing assembly of claim 1, further comprising:
one or more first power supply circuits coupled to the first coil assembly and configured to drive the one or more first coils; and
one or more second power supply circuits coupled to the second coil assembly and configured to drive the one or more second coils.

12. A method of processing a substrate, the method comprising performing a processing sequence on the substrate disposed within a processing region of a plasma processing assembly, wherein the processing sequence comprises:
biasing, using one or more first power supply circuits, at least one of one or more first coils included in a first coil assembly, wherein
windings of the one or more first coils are aligned in a first direction and at least partially encircle the processing region,
the first coil assembly is disposed inside a first region of the processing region formed by a plasma screen disposed within the processing region, and
the first direction is at an angle to a plane of the substrate supporting surface in the plasma processing assembly; and
biasing, using one or more second power supply circuits, at least one of one or more second coils included in a second coil assembly, wherein
the one or more second coils at least partially encircle the processing region, and
the second coil assembly is disposed inside a second region of the processing region formed by the plasma screen.

13. The method of claim 12, wherein the first coil assembly is coupled to a chamber liner included in the plasma processing assembly.

14. The method of claim 12, wherein the second coil assembly is coupled to the plasma screen, and wherein the plasma screen comprises one or more openings.

15. The method of claim 12, wherein the second coil assembly is embedded in the plasma screen, and wherein the plasma screen comprises one or more openings.

16. The method of claim 12, wherein the one or more first coils comprise at least two concentrically wound coils, and wherein at least one of:
the at least two concentrically wound coils are wound in different directions;
the at least two concentrically wound coils have different numbers of turns; or
the at least two concentrically wound coils have different core sizes.

17. The method of claim 12, wherein the one or more second coils comprise at least two concentrically wound coils, and wherein at least one of:
the at least two concentrically wound coils are wound in different directions;
the at least two concentrically wound coils have different numbers of turns; or
the at least two concentrically wound coils have different core sizes.

18. A plasma processing assembly comprising:
a processing chamber including a processing region;
a plasma screen disposed within the processing region that forms a first region of the processing region and a second region of the processing region;
a substrate support assembly disposed within the processing region, the substrate support assembly comprising a substrate supporting surface; and
a field generation system comprising:
a coil assembly comprising one or more concentrically wound coils, wherein
windings of the one or more concentrically wound coils are aligned in a direction and at least partially encircle the processing region,
the coil assembly is disposed inside the first region, and
the direction is at an angle to a plane of the substrate supporting surface.

19. The plasma processing assembly of claim 18, wherein the substrate support assembly comprises a central axis that is aligned perpendicular to the substrate supporting surface.

20. The plasma processing assembly of claim 18, wherein the one or more concentrically wound coils comprise at least two concentrically wound coils, and wherein at least one of:
the at least two concentrically wound coils are wound in different directions;
the at least two concentrically wound coils have different numbers of turns; or
the at least two concentrically wound coils have different core sizes.
